(19) United States
(12) Patent Application Publication
(10) Pub. No.: US 2006/0278470 A1
(43) Pub. Date: Dec. 14, 2006

(54) Ceiling mounting speaker stand system

(75) Inventor: Andrea Carola, London (GB)

Correspondence Address: SEYFARTH SHAW LLP, 131 S. DEARBORN ST., SUITE2400, CHICAGO, IL, 60603-5803, US

(73) Assignee: Intersource Product Development Ltd.

(21) Appl. No.: 11/147,837

(22) Filed: Jun. 8, 2005

(51) Int. Cl. H05K 5/00

(52) U.S. Cl. 181/150

(57) ABSTRACT

A mounting system for loudspeakers composed of a multiple frame which retain 2 or 4 loudspeakers and a set of single frames which host one loudspeaker such that loudspeakers of standard manufacturing size and type can be mounted to the ceiling of a listening space.

The invention relates to stands for mounting loudspeakers. and particularly for mounting loudspeakers on the ceiling of the listening area. Where the term stand refer to the type of product, consisting of supports designed to host loudspeakers at a different height from the floor level.

Loudspeakers are normally mounted at the periphery of a listening area to direct sound output from the speakers towards a central point; this type of speaker arrangement is referred to hereinafter as a ‘convergent’ configuration. Though such speaker arrangement results in a high quality and balance of sound in the central region of the listening area, the sound quality, intensity and balance in the outer regions of the listening area are generally of a lower standard. It could be argued that the loudspeakers should be placed in other points and mounted the ceiling of the listening area; this can result in improved sound properties given that other dispositions can be achieved; among which placing the speaker so to direct sound in a divergent configuration. However, to date, sound systems suitable for ceiling mounting of loudspeakers have not been widely available.

The present invention provides a multiple ceiling mounting stand for mounting a plurality of loudspeakers. The stand comprising a plurality of housings mounted on a central frame, each housing receiving and securely retaining a loudspeaker, whereby the speakers are mounted in a divergent or radial configuration. The mounting stand is suspended to ceiling.

The present invention provide as well single ceiling mounting stands for additional set of speakers to be mounted separately from one another at different point of the listening area.

The invention provides simple and inexpensive apparatus capable of mounting speakers from an existing sound system to the ceiling.

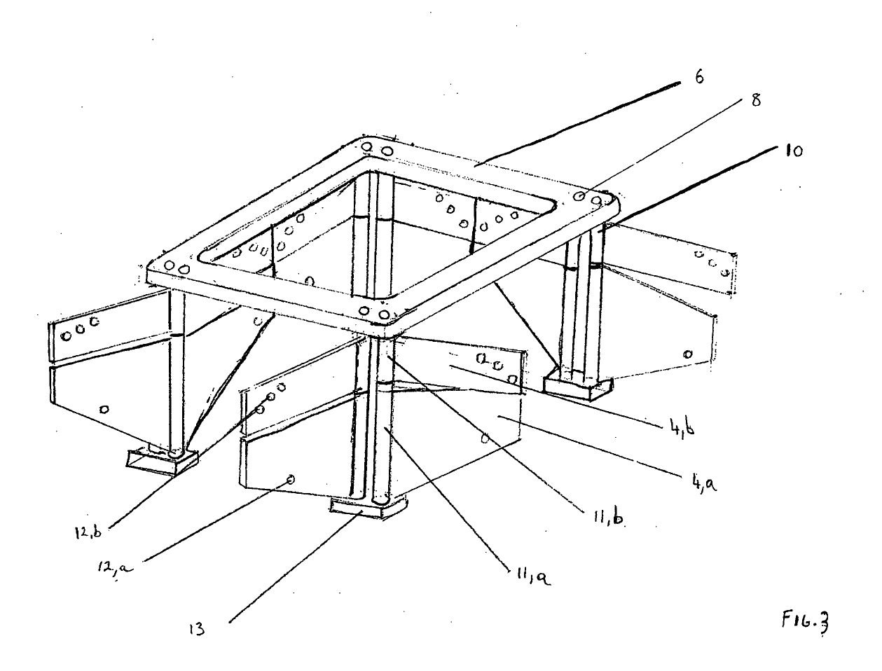

The multiple frame (FIG. 3) comprises upper rectangular structure 6. The confronting faces—of the structures 6 have two tapped mounting holes 8 provided on the longitudinal axis of the longer pair of sides adjacent each corner to receive cylindrical threaded rods or pipes 10. The rods 10 project perpendicularly to the plane of the structures 6 to define therewith a generally cubical frame. A pair of cylindrical tube 11's are mounted on each of the rods 10 for pivotal movement about a vertical axis. Supporting arms 4a,4b project from each tube to meet pivots openings 12a and 12b's . The tubes are similarly firmed together pairwise by 4 rectangular bar (13) at the opposite ends in correspondence of each of the 4 corners. The frame may be attached to the ceiling of a listening area by any appropriate support or bracket.

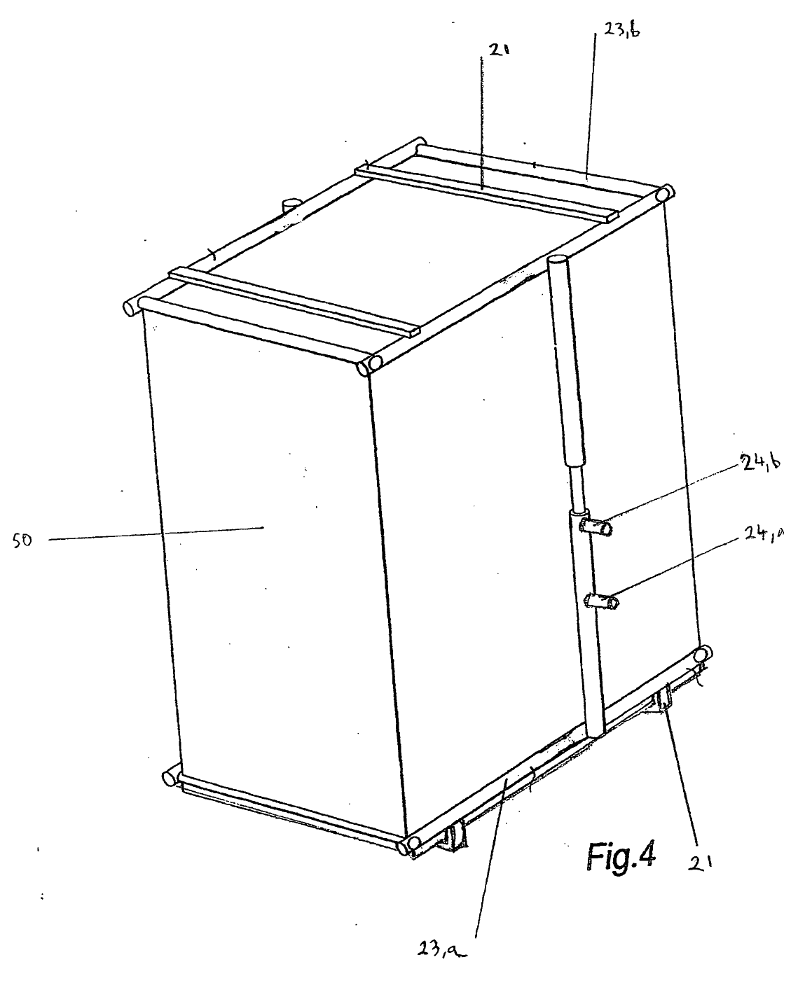

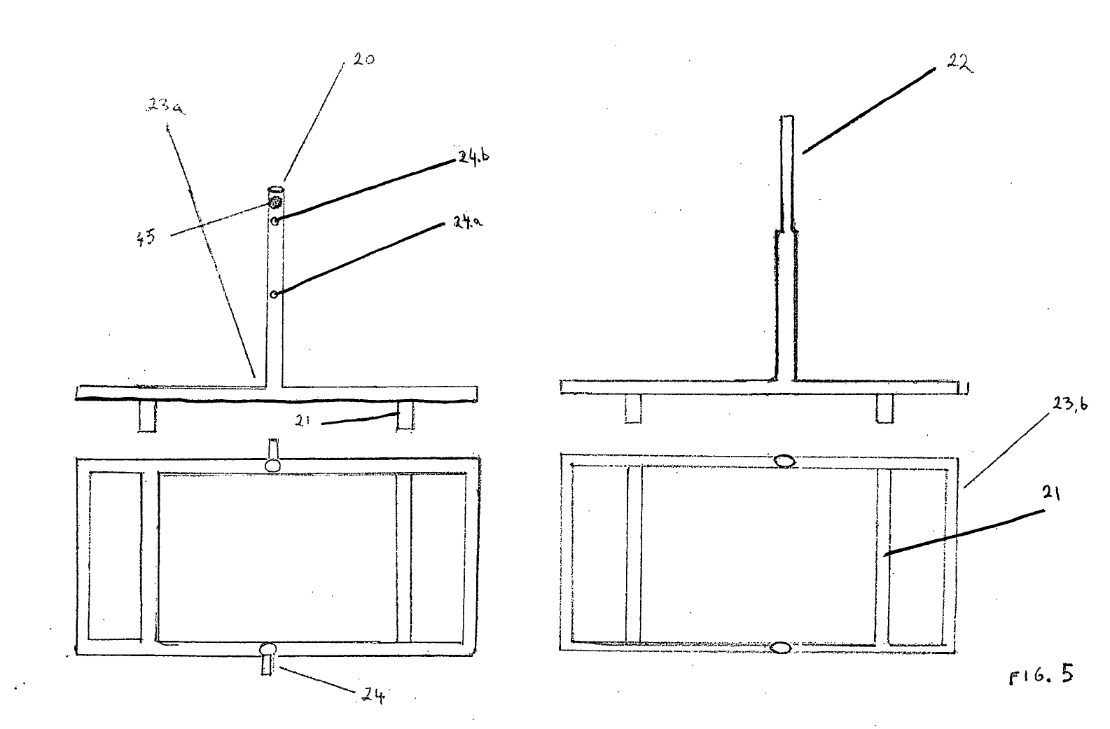

Each housing (FIG. 5) has two component parts. Two similar trays—have bottom reinforcement struts 21. The free ends 20 receive the free ends 22 of the upper portion in a sliding-fit engagement to form lower and upper support surfaces of the housing. By adjusting the position of the two housing portions 23a and 23b the height can be adjusted. The speaker is firmed between bottom supports 21's of both the components 23,a and 23b and front tubular frame 25. This housing leaves the front of the speaker free from any parts crossing its outward face. Clamping 45, screws or other releasable fastening elements are provided to secure the housing portions. Further the housings may be mounted on the frame(s) for rotation. (FIG. 4) where the housings may be releasably fastened on the frame at preselected angle to the vertical's by means of ends 24a, 24b.

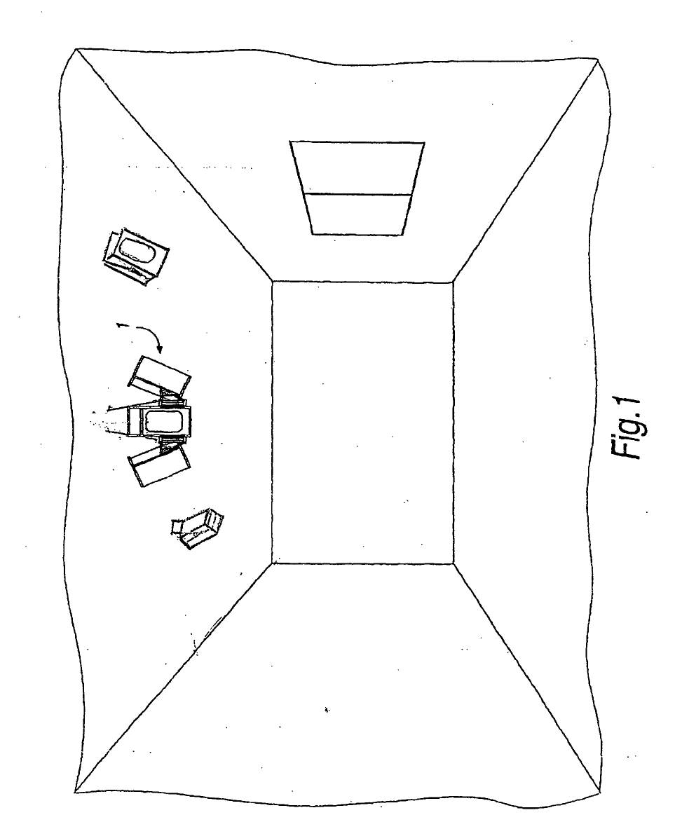

The multiple mounting stand is secured to the centre of the ceiling of the listening area (FIG. 1)

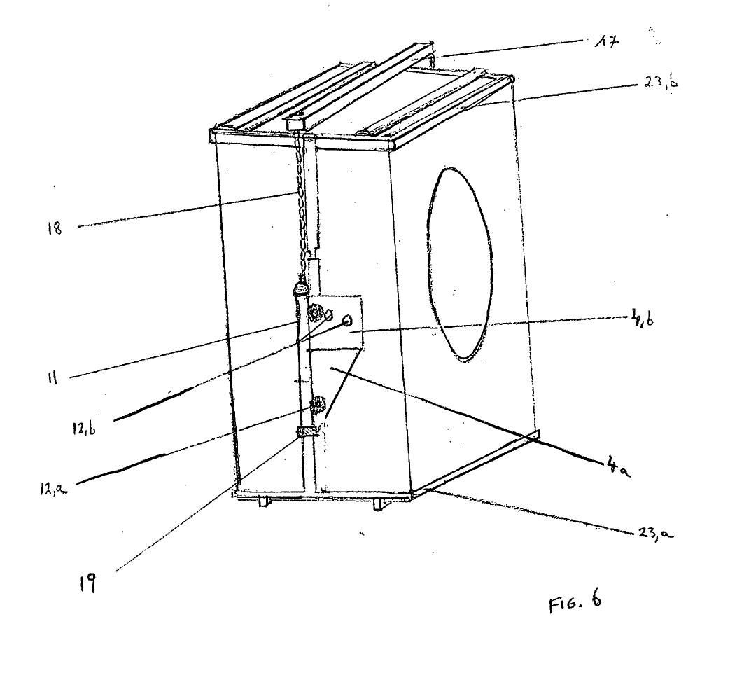

Additional single mounting stands (FIG. 6) are formed by 1 longitudinal bar (17) from which departs a string or chain (18) that receive the cylindrical rods (10) and cylindrical tubules (11) and lateral supports 4's whose shape will differ from lateral arms of the rain mounting stand to the extent that the former will be shorter in width where pivot openings 12a, 12b's are positioned immediately next to cylindrical tubes (11) such that the line formed by the pivot openings 12a, and 12b and the longitudinal bar will be perpendicular to the ceiling plane (see FIG. 6). Similarly 2 bolts (19) firm each of the cylindrical tubes (11) from the bottom. The speaker housing is adapted in the same fashion to the lateral arms 4's as for the main mounting stand. This single mounting stand hosts a single speaker.

The single mounting stand is suspended to the ceiling at specific points. ( FIG. 1)

In order to interpret the text, the following is a detailed description of the invention with reference to the accompanying drawings in which:

FIG. 1 is an illustrative view of a ceiling stand system according to the description consisting of a system of 6 speakers arranged in a divergent (radial) configuration;

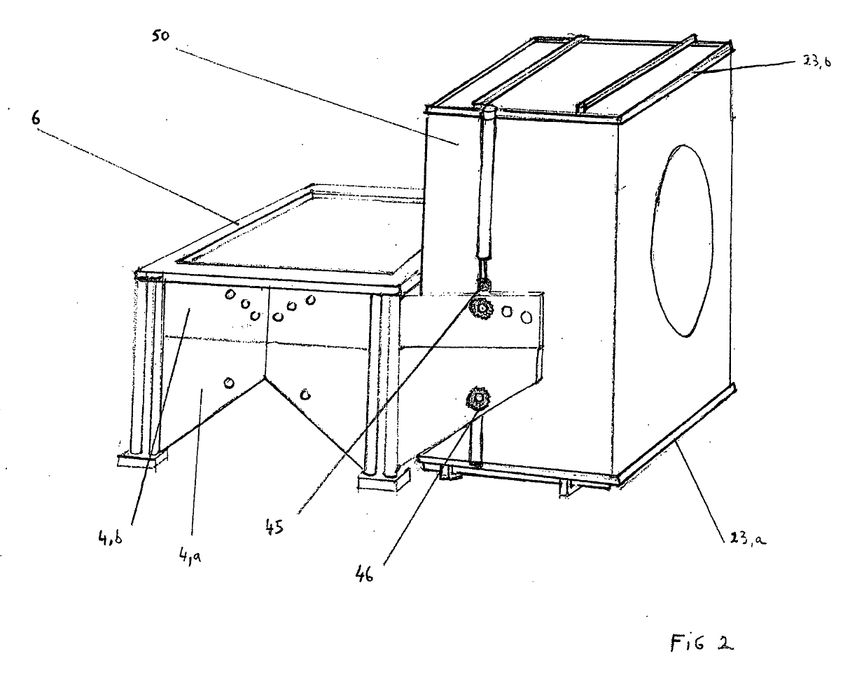

FIG. 2 is an illustrative view of the multiple stand shown in FIG. 1 with a single housing mounted to the central frame;

FIG. 3 is an illustrative view of the multiple frame;

FIG. 4 is an illustrative view of the housing shown in FIG. 2;

FIG. 5 shows front and side views of the components of the housing; and

FIG. 6 is an illustrative view of the single mounting speaker stand.

To begin assembling of the various components of the ceiling mounting stand, a loudspeaker 50 is placed in element 23a of housing (FIG. 4) with its front side adjacent the outer edge, element 23b is mounted and the housing height adjusted according to the size of the speaker. The housing and the speaker are mounted to the multiple frame or to the single frame; end (24a) is fitted in opening 12a) of lateral arms 4a, the vertical angle adjusted to position, in order to facilitate this process the upper lateral arm 4b is disjoint from the lower 4a. End (24b) fitted in any opening 12b); clamping screws (46) are tightened. The housing components is in position and thus secures the loudspeaker within the housing. The other three loudspeakers are mounted to the frame in similar fashion. Additionally other speakers on single mounting stands (FIG. 6) are mounted in the same fashion at specific points (FIG. 1). The multiple and the single frames may be permanently or releasably mounted to the ceiling of the listening area by any appropriate means.

Of course modification of the preferred embodiment are possible without departing form the spirit of the invention. For instance the frame could be adapted to receive any size of loudspeakers, or the multiple frame could be echtagonal to support six speakers. the various components may be manufactured form metal, aluminum, plastic or other suitable material.

1. A mounting mean for mounting a plurality of loudspeakers, comprising a plurality of: loudspeakers housings mounted on a rectangular central frame, each housing receiving and securely retaining a loudspeaker, wherein in use the loudspeakers are mounted on a divergent or radial configuration to the ceiling of a listening space is known prior art from same applicant. (see Loudspeaker Mounting Apparatus—: 00304986.3)
A set of mounting means which in addition to the multiple mounting frame comprises sets of single mounting means for hosting single loudspeakers to be mounted in a similar fashion to the ceiling in various points, defines the present invention.

2. A multiple mounting mean as in the preceding claim in which pair of lateral arms can rotate around their vertical axis by means of cylinders connected to each side of a central rectangular frame. (FIG. 3)

3. A multiple mounting mean according to claim 2 wherein more loudspeakers housing are demountably secured to the frame by means of lateral arms (FIG. 2) and pivot ends (FIG. 4).

4. A multiple mounting mean as of claim 3 claim wherein the relative positions of the housing components of each loudspeakers housing are adjustable such that loudspeakers of different height can be received and securely retained in the housing. (FIG. 4)

5. A multiple mounting means as in claim 4, in which to allow the height adjustment each housing is formed of two elements, the top element has an end which by mean of a sliding movement is blocked in the bottom element female equivalent by mean of a screw. (FIG. 5)

6. A multiple mounting mean according to claim 3, wherein the loudspeaker housings are pivotally mounted for rotation about a pivot point or end positioned around a midpoint in relation of both the height and the width of lateral tubular reinforcement of each housing.

7. A multiple mounting mean as in claim 6 and 3 in which each loudspeaker, once positioned in the housing, can be releasably secured at selected angle to the vertical to the central frame. Wherein lateral arms departing from the central frame have openings to which to adjust the housing inclination according to a selected position. (FIG. 2)

8. A multiple mounting mean as in claim 7 in which to facilitate the adjusting of the housing to the position lateral arms are formed by separate elements where the lower arm secures the housing pivot point or end, and, the upper arm closes to match the chosen opening with the second upper end on the housing lateral tubular reinforcement.

9. A multiple mounting mean as in claims 1 in which means are provided for suspending the frame to the ceiling.

10. A set of mounting means which, in addition to the central frame, has separate single mounting means (FIG. 6) consisting of longitudinal frame(s) or bars from which departs 2 cylindrical elements rotating around the vertical axis, each forming a pair of lateral arms of which the bottom has one pivot opening and the top multiple openings, where the line formed by the pivot point, the selected opening, and the longitudinal bar at the point in which it cross it, is a straight line perpendicular to the ceiling plane when the frame bar is mounted.

11. An apparatus as in claim 10 in which one loudspeaker housing can be secured and adjusted to the single frame at selected angle from the vertical by means of openings on the lateral arms and pivot ends on the lateral tubular reinforcement of the housing.

12. An apparatus as in any of the preceding claim that can form a sound systems of 2, 4 or more speakers; mounted to the ceiling of a listening space (FIG. 1) at a central point in a divergent configuration in group of 2 or 4, and, additionally, mounted individually to the ceiling at different distances from the center.
